(19) United States
(12) Patent Application Publication
(10) Pub. No.: US 2005/0146265 A1
(43) Pub. Date: Jul. 7, 2005

(54) Production method for electric filed luminous body electric field luminous body pattening method and electric field light emitting display device

(76) Inventors: Takashi Fukuchi, Tokyo (JP); Shinzo Tsuboi, Tokyo (JP); Tsutomu Minami, Osaka (JP); Masahiro Tatsumisago, Osaka (JP); Kiyoharu Tadanaga, Osaka (JP); Atsunori Matsuda, Osaka (JP)

Correspondence Address: Norman P Soloway;Hayes Soloway, 130 W Cushing Street, Tucson, AZ, 85710, US

(21) Appl. No.: 10/494,799

(22) PCT Filed: Nov. 7, 2002
(86) PCT No.: PCT/JP02/11625

(30) Foreign Application Priority Data
Nov. 7, 2001 (JP) 2001-341506

(51) Int. Cl. H05B 33/00; H05B 33/10

(52) U.S. Cl. 313/506; 313/509; 313/504; 427/66; 445/24

(57) ABSTRACT

A water-repellent/oil-repellent material that is decomposed to disappear by light irradiation is used to eliminate a water-repellent/oil-repellent layer on ITO electrodes. By forming light emitting layers in regions subjected to the elimination, patterning is carried out.

### TECHNICAL FIELD

The present invention relates to an electroluminescent body (electroluminous body) for use in an information display device such as a television, a computer, a game device, a portable information terminal, or a portable telephone, an electroluminescent display device using it, and a production method thereof.

### BACKGROUND ART

An electroluminescent display device comprises a large number of electroluminescent bodies (hereinafter electroluminescent or electroluminescent body may also be referred to as EL). Among-the electroluminescent bodies, one example of a structure of, for example, an organic EL element is such that a lower electrode in the form of a transparent thin film of ITO or the like is formed on a transparent substrate of glass or the like, then a light emitting layer (A structure in which a hole transport layer, an organic EL layer, an electron transport layer, and the like are stacked together is collectively called a light emitting layer. Further, either or both of the hole transport layer and the electron transport layer each being a carrier layer may be omitted.) is stacked thereon, and further an upper electrode made of an aluminum-lithium alloy, a silver-magnesium alloy, a silver-calcium alloy, or the like is formed thereon. By arraying a large number of such EL elements to form an electroluminescent display device and causing the proper elements to emit light in accordance with an input signal, a desired image is displayed. By arraying a large number of minute EL elements that emit red (R), green (G), and blue (B) light and adjusting the luminous intensities of the respective elements, more colors are displayed. For displaying a finer image or displaying more colors, it is necessary that respective EL elements be more minute and a large number of them be arrayed.

In general, the photolithography is employed as a method of forming minute elements. However, with respect to the organic EL elements, the photolithography can not be employed in terms of mainly a chemical stability of an organic EL material. As a patterning method of the EL material, Publication of Patent No. 1526026, for example, describes a method (deposition method) of forming films by depositing an EL material via a metal mask. Further, Publication of Patent No. 3036436 describes a method (inkjet method) of forming films by discharging a solution containing an EL material as minute droplets to hit at predetermined positions using the inkjet method. Furthermore, Unexamined Patent Publication No. 2000-223070 describes a method (siloxane method) of forming EL elements using a patterning layer made of a photocatalyst and organopolysiloxane and utilizing the fact that the surface leakage property of the patterning layer relative to a stacking material is improved by light irradiation.

For providing an EL display device with high fineness, with high efficiency, with a large screen, and at a low cost which can not be realized by the currently known EL patterning methods, there are problems in the conventional techniques as described below.

In the foregoing deposition method, it is impossible to realize the fineness higher than the present state due to the fact that it is necessary to repeat deposition for each of R, G, and B colors so that arraying a large number of minute EL pixels is subject to limitation particularly in terms of positioning accuracy of the metal mask. Further, it is difficult to increase the size of a substrate in terms of thermal expansion of the metal mask, and further, since there is a limitation on multiple patterning, the production cost increases with respect to a small-sized EL display device.

In the foregoing inkjet method, it is impossible to realize the fineness higher than the present state due to the fact that it is necessary to drop the droplets containing the EL material at the predetermined positions so as not to be mixed with adjacent pixels so that arraying a large number of minute EL pixels is subject to limitation particularly in terms of hitting position accuracy of the, droplets. Further, since it is necessary to provide partitions between the adjacent pixels for holding the hit droplets in position, the production cost increases.

In the foregoing siloxane method, a layer of silicon oxide being a decomposition product of the photocatalyst and organopolysiloxane remains between an electrode and a light emitting layer of the formed EL element, so that the electrical resistance of the EL element increases to reduce the luminous efficiency.

### DISCLOSURE OF THE INVENTION

As a result of repeating assiduous studies for solving the foregoing problems, the present inventors have reached the present invention. Specifically, the present invention differs from the deposition method, the inkjet method, or the siloxane method, but is a patterning method of using a water-repellent/oil-repellent material that is decomposed to disappear by light irradiation, so as to eliminate a water-repellent/oil-repellent layer on an ITO electrode to thereby form a light emitting layer in a region subjected to the elimination.

In this method, it is not necessary to provide a photocatalyst layer, and there does not remain silicon oxide being a decomposition product of the water-repellent/oil-repellent material on the ITO electrode after light irradiation. Further, since patterning eliminating the water-repellent/oil-repellent layer is carried out by the light irradiation, it is excellent in position accuracy as compared with the deposition method and does not require the partitions between pixels that are essential in the inkjet method. Moreover, since the formation of the light emitting layer is carried out by the spin coat method, the dip method, the minute nozzle application method, or the like, an expensive patterning apparatus such as a deposition apparatus or an inkjet apparatus is not necessary.

A substrate of an EL element used in the present invention has no limitation except that a lower electrode should be formable and, although a material thereof can be exemplified by glass, plastics, silicon, or the like, it is not limited to these examples. Further, with respect to the area and the thickness of the substrate, there is no limitation at all by the present invention. With respect also to a driving circuit, there is no limitation at all by the present invention. Although a material of the lower electrode can be exemplified by In₂₋ₓSnₓO₃(ITO), In₂₋ₓZnₓO₃, or the like, as long as it contains indium oxide, tin oxide, or zinc oxide and has a property of decomposing PFPE by light irradiation, it is not limited to these examples. Further, with respect also to its film thickness and pattern shape, there is no limitation at all by the present invention. Although a material of a water-repellent/oil-repellent layer can be exemplified by compounds given by General Formulas 1 to 4 shown below, it is not limited to these examples.
G-(CF₂)ₙ-G General Formula 1
G-(CF₂—CF₂—O)ₚ—(CF₂—O)_{q}-G General Formula 2
G-(CF₂—CF₂—O)ₚ-G General Formula 3
G-(CF(CF₃)—CF₂—O)ₚ—CF(CF₃)-G General Formula 4
where n represents an integer of 1 to 18, G independently represents F, CH₂—OH, or COOH, and p and q independently represent integers of 1 to 8, respectively.

There is no particular limitation about the film thickness thereof. Further, there is no particular limitation about a film forming method of this water-repellent/oil-repellent layer and, although it can be exemplified by the spin coat method, the dip method, the deposition method, or the like, it is not limited to these examples. A photomask transmits or does not transmit irradiated light in accordance with a desired pattern, and there is no other limitation. Irradiation light is only required to have a property of decomposing the water-repellent/oil-repellent layer by being irradiated to the electrode, and there is no limitation about its intensity, irradiation angle, irradiation time, and frequency. Further, such an electromagnetic wave and an electromagnetic wave not having a property of decomposing the water-repellent/oil-repellent layer alone even by being irradiated to the electrode, may be simultaneously irradiated. A light emitting layer may be a monolayer or may have a stack structure composed of a hole transport layer, an organic EL layer, an electron transport layer, and the like. Further, the kind of solvent for dissolving a material thereof has no limitation except that it is other than one that dissolves the water-repellent/oil-repellent layer. Further, there is no particular limitation about the concentration of a solution thereof. A film forming method of the light emitting layer can be exemplified by the spin coat method, the dip method, the spray method, the nozzle injection method, the print method, the transfer method, or the like, but is not limited to these examples. Further, the inkjet method can also be used. A material of an upper electrode can be exemplified by an aluminum-lithium alloy, a silver-magnesium alloy, a silver-calcium alloy, or the like, but is not limited to these examples. The film thickness thereof also has no particular limitation and, although a film forming method thereof can be exemplified by the deposition method, the print method, or the like, it is not limited to these examples.

Further, according to the present invention, there is also provided a patterning method characterized by providing, on a substrate, a patterning layer having a surface leakage property relative to a stacking material which is different from that of the substrate, and forming a pattern of said stacking material by partly eliminating said patterning layer and utilizing a difference in surface leakage property between an exposed portion of the substrate and the patterning layer.

In this patterning method, a material forming the patterning layer having the surface leakage property relative to the stacking material different from that of the substrate may comprise a compound that produces only a gaseous decomposed substance when photodecomposed by a semiconductor photocatalyst.

Furthermore, according to the present invention, there is obtained a patterning method characterized by comprising a step of providing a patterning layer on a substrate formed with a pattern made of a material containing at least a semiconductor photocatalyst, the patterning layer having a surface leakage property relative to a stacking material which is different from that of a surface of said pattern; a step of irradiating an electromagnetic wave including an energy component equal to or greater than a bandgap of the semiconductor photocatalyst, to the whole surface of the substrate or a region including said pattern for photodecomposing and eliminating the patterning layer on said pattern; and a step of forming a pattern of said stacking material utilizing a difference in surface leakage property between the patterning layer and the surface of said pattern.

In this patterning method, a photomask for forming a non-irradiated region on the substrate may not be used upon irradiating the electromagnetic wave including the energy component equal to or greater than the bandgap of the semiconductor photocatalyst, to the whole surface of the substrate or the region including the pattern made of the material containing the semiconductor photocatalyst.

In the foregoing two patterning methods, it is considered that the patterning layer is a water-repellent/oil-repellent layer and the water-repellent/oil-repellent layer contains one of compounds identified by the following General Formulas 1 to 4.
G-CF₂—(CF₂)ₛ—CF₂-G General Formula 1
G-(CF₂—CF₂—O)ₚ—(CF₂—O)_{q}-G General Formula 2
G-(CF₂—CF₂—O)ᵣ-G General Formula 3
G-(CF(CF₃)—CF₂—O)ₚ—(CF(CF₃)—O)_{q}-G General Formula 4
where G independently represents F, CH₂—OH, COOH, NH₂ or a benzodioxol group, s represents an integer of 0 to 500, p and q independently represent integers of 0 to 100, respectively, and r represents an integer of 1 to 200.

In these patterning methods, the patterning layer may be a water-repellent/oil-repellent layer, and light irradiated to a region including a portion, corresponding to a lower electrode pattern, on the water-repellent/oil-repellent layer may be ultraviolet light, ultraviolet light and visible light, or an electromagnetic wave including ultraviolet light and a microwave.

Further, according to the present invention, there is obtained a method of producing an electroluminescent body in which a lower electrode pattern is formed on a substrate, a light emitting layer is formed on the lower electrode pattern, an upper electrode is formed on the light emitting layer, and at least one of the lower electrode and the upper electrode is transparent, the method characterized by comprising a step of providing a patterning layer on the substrate formed with the lower electrode pattern; a step of irradiating an electromagnetic wave including ultraviolet light to the whole surface of the substrate provided with the patterning layer or a region including the lower electrode pattern; a step of stacking at least the light emitting layer on the lower electrode where the patterning layer is eliminated; and a step of forming the upper electrode in a region including an upper surface of the light emitting layer.

In addition, there is obtained a method of producing an electroluminescent body in which a lower electrode pattern is formed on a substrate, a light emitting layer is formed on the lower electrode pattern, an upper electrode is formed on the light emitting layer, and at least one of the lower electrode and the upper electrode is transparent, the method characterized by comprising a step of forming a water-repellent/oil-repellent layer on the substrate formed with at least the lower electrode pattern; a step of irradiating light to a region including a portion, corresponding to the lower electrode pattern, on the water-repellent/oil-repellent layer to cause a water-repellent/oil-repellent property on the lower electrode pattern to be lost; a step of forming the light emitting layer in the region where the water-repellent/oil-repellent property is lost; and a step of forming the upper electrode on the formed light emitting layer.

In these electroluminescent body producing methods, it is considered that the patterning layer is a water-repellent/oil-repellent layer and the water-repellent/oil-repellent layer contains one of compounds identified by the following General Formulas 1 to 4.
G-CF₂—(CF₂)ₛ—CF₂-G General Formula 1
G-(CF₂—CF₂—O)ₚ—(CF₂—O)_{q}-G General Formula 2
G-(CF₂—CF₂—O)ᵣ-G General Formula 3
G-(CF(CF₃)—CF₂—O)ₚ—(CF(CF₃)—O)_{q}-G General Formula 4
where G independently represents F, CH₂—OH, COOH, NH₂ or a benzodioxol group, s represents an integer of 0 to 500, p and q independently represent integers of 0 to 100, respectively, and r represents an integer of 1 to 200.

In these electroluminescent body producing methods, the patterning layer may be a water-repellent/oil-repellent layer, and light irradiated to a region including a portion, corresponding to the lower electrode pattern, on the water-repellent/oil-repellent layer may be ultraviolet light, ultraviolet light and visible light, or an electromagnetic wave including ultraviolet light and a microwave.

Further, the patterning layer may be a water-repellent/oil-repellent layer, and a method of forming the light emitting layer in a region where a water-repellent/oil-repellent property is lost may include at least one kind of method in a spin coat method, a dip method, a spray method, a minute nozzle injection method, a print method, and a transfer method.

Further, the patterning layer may be a water-repellent/oil-repellent layer and, after forming the light emitting layer, the water-repellent/oil-repellent layer may be removed from the substrate by immersing the substrate in an organic solvent having a property of dissolving the water-repellent/oil-repellent layer.

Further, the patterning layer may be a water-repellent/oil-repellent layer and, after forming the light emitting layer, the water-repellent/oil-repellent layer may be removed from the substrate by contacting the water-repellent/oil-repellent layer on the substrate with an organic solvent having a property of dissolving the water-repellent/oil-repellent layer.

It is considered that a method of forming the upper electrode on the formed light emitting layer includes at least one kind of method in a deposition method, a sputtering method, and a print method.

It is considered that, as a material of the lower electrode forming the pattern or the upper electrode, one or both of them contain at least one kind of titanium oxide, indium oxide, tin oxide, and indium-tin composite oxide (ITO).

Further, according to the present invention, there is obtained an electroluminescent body in which a lower electrode pattern is formed on a substrate, a light emitting layer is formed on the lower electrode pattern, an upper electrode is formed on the light emitting layer, and at least one of the lower electrode and the upper electrode is transparent, the electroluminescent body characterized by having a structure in which no partition exists between adjacent light emitting layers.

In addition, there is obtained an electroluminescent body in which a lower electrode pattern is formed on a substrate, a light emitting layer is formed on the lower electrode pattern, an upper electrode is formed on the light emitting layer, and at least one of the lower electrode and the upper electrode is transparent, the electroluminescent body characterized by having a structure in which the light emitting layer is not formed inside a hole.

Further, there is obtained an electroluminescent body in which a lower electrode pattern is formed on a substrate, a light emitting layer is formed on the lower electrode pattern, an upper electrode is formed on the light emitting layer, and at least one of the lower electrode and the upper electrode is transparent, the electroluminescent body characterized by having a structure in which a patterning layer is formed in a region on the substrate where the lower electrode does not exist, while is not formed on the lower electrode.

It is considered that a water-repellent/oil-repellent layer used as the patterning layer of the electroluminescent body contains one of compounds identified by the following General Formulas 1 to 4.
G-CF₂—(CF₂)ₛ—CF₂-G General Formula 1
G-(CF₂—CF₂—O)ₚ—(CF₂—O)_{q}-G General Formula 2
G-(CF₂—CF₂—O)ᵣ-G General Formula 3
G-(CF(CF₃)—CF₂—O)ₚ—(CF(CF₃)—O)_{q}-G General Formula 4
where G independently represents F, CH₂—OH, COOH, NH₂ or a benzodioxol group, s represents an integer of 0 to 500, p and q independently represent integers of 0 to 100, respectively, and r represents an integer of 1 to 200.

Further, according to the present invention, there is obtained an electroluminescent body wherein at least one of a lower electrode pattern and an upper electrode is transparent and there are, on a substrate, both a region where the lower electrode pattern and a patterning layer are formed in order from below and a region where the lower electrode pattern, a light emitting layer, and the upper electrode are formed in order from below.

In this electroluminescent body, it is considered that the patterning layer is a water-repellent/oil-repellent layer.

This electroluminescent body may have a structure in which a pattern is formed in both or one of at least the lower electrode and the upper electrode, and the light emitting layer is formed in a region covering this electrode pattern. Alternatively, the electroluminescent body may have a structure in which a pattern is formed in both or one of at least the lower electrode and the upper electrode, a region including a portion, corresponding to this electrode pattern, of the substrate is formed concave, and the light emitting layer is formed in this concave region. Alternatively, the electroluminescent body may have a structure in which a pattern is formed in both or one of at least the lower electrode and the upper electrode, an outer edge portion of a region, corresponding to this electrode pattern, of the substrate is formed convex, and the light emitting layer is formed inside this convex region.

In these electroluminescent bodies, it is considered that one or both of the lower electrode forming the pattern and the upper electrode contain at least one kind of titanium oxide, indium oxide, tin oxide, and indium-tin composite oxide (ITO).

Further, according to the present invention, there is obtained an electroluminescent display device characterized by comprising the foregoing electroluminescent body.

### BRIEF DESCRIPTION OF THE DRAWINGS

FIG. 1 is an exemplary diagram showing structures of electroluminescent elements produced in Example 1 of the present invention;

FIG. 2 is an exemplary diagram showing structures of electroluminescent elements produced in Example 2 of the present invention;

FIG. 3 is an exemplary diagram showing structures of electroluminescent elements produced in Example 3 of the present invention;

FIG. 4 is an exemplary diagram showing structures of electroluminescent elements produced in Example 4 of the present invention;

FIG. 5 is an exemplary diagram showing structures of electroluminescent elements produced in Examples 5 to 7 of the present invention;

FIG. 6 is an exemplary diagram showing structures of electroluminescent elements produced in Example 8 of the present invention;

FIG. 7 is an exemplary diagram showing structures of electroluminescent elements produced in Example 9 of the present invention; and

FIG. 8 is an exemplary diagram showing structures of electroluminescent elements produced in Example 10 of the present invention.

### BEST MODE FOR CARRYING OUT THE INVENTION

### 1. FIRST EMBODIMENT

At the outset, description will be made of a production method of an EL display device being one embodiment of the present invention. The EL display device produced herein comprises active matrix·lower surface light emitting type EL elements.

A film of a water-repellent/oil-repellent material is formed on the whole substrate that is formed with circuits for driving the EL elements and with ITO lower electrodes. This material is fluorocarbon with polytetrafluoroethane or perfluoropolyether in the main chain (hereinafter referred to as PFPE). When ultraviolet light is irradiated to the substrate having a water-repellent/oil-repellent layer obtained by forming the film of the PFPE, via a photomask with drawn regions where the water-repellent/oil-repellent layer is to be eliminated, the PFPE is decomposed by the action of indium oxide or tin oxide in the ITO lower electrodes within the regions where the light is irradiated passing through the photomask, so that decomposition products all become gas to disappear from over the ITO lower electrodes. Thus, the non-water-repellent/oil-repellent regions are formed in the water-repellent/oil-repellent layer. A light emitting layer is formed as a film on this substrate by the spin coat method, the dip method, or the like. However, due to a strong water-repellent/oil-repellent property of the PFPE, absolution of each of materials forming the light emitting layer spontaneously gathers to the non-water-repellent/oil-repelient regions whether it is an aqueous solution or an oil solution such as toluene or xylene. Therefore, by forming as films and stacking in order respective organic layers forming the light emitting layer, it is possible to form the light emitting layers only in the non-water-repellent/oil-repellent regions. Further, an upper electrode made of a silver-calcium alloy or the like is formed on the light emitting layers so that the EL display device can be produced with high accuracy and high efficiency and at low cost.

Hereinbelow, the present invention will be described in detail by examples.

### EXAMPLE 1

### An Electroluminescent Body Producing Method Using a Substrate with Pixel Regions Formed Flat, an Electroluminescent Body, and an Electroluminescent Display Device

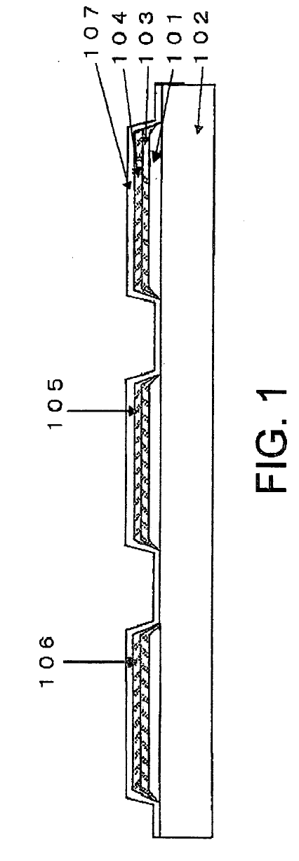

Description will be made referring to FIG. 1. Using a glass substrate (500 mm×500 mm, thickness 0.7 mm, 102 in FIG. 1) formed with circuits for driving active matrix EL elements and with a pattern arranged with a large number of ITO lower electrodes (101 in FIG. 1) (electrode 61.0 cm×37.3 μm, an interval between the electrodes is 66.0 μm in a long-side direction of the electrode and 5 μm in a short-side direction thereof), formation of red light emitting layers each (hole transport layer+EL layer) was carried out on a surface of the substrate in the following manner.

As a water-repellent/oil-repellent layer, HO—CH₂—(CF₂)₈—CH₂—OH (PFPE1) was formed into a film by the spin coat method. Specifically, 500 ml of an FC-77 (produced by Sumitomo 3M Limited) solution of PFPE1 (0.024%) was dropped onto the substrate using a pipette, then the substrate was rotated at high speed (2000 rpm) and dried under normal pressure at 60° C. for 30 minutes (film thickness 2 nm). When the number of CF₂ (value of n in General Formula 1) in a PFPE1 molecule exceeded 18, the solubility thereof relative to the solvent such as FC-77 was extremely lowered so that an excellent water-repellent/oil-repellent layer could not be obtained. On the other hand, when the film thickness of PFPE1 was less than 0.1 nm, a continuous film was not obtained, thus resulting in impracticality. Further, when the film thickness thereof exceeded 100 μm, the-pattern accuracy achieved by light irradiation deviated from a practical range. This film thickness range was common to PFPE2, PFPE3, and PFPE4 which will be described in Examples 2 to 4.

A photomask having openings (opening 61.0 μm×37.3 μm, the width of a light shielding portion between the openings is 89.6 μm in a short-side direction of the opening and 66.0 μm in a long-side direction of the opening) at positions, which will be red EL elements, in the lower electrode pattern was tightly adhered to the substrate formed with the film of PFPE1, and ultraviolet light (70 mW/cm²) having a center wavelength of 290 nm was irradiated for five minutes. PFPE1 in ultraviolet light irradiated regions was decomposed to disappear, thereby exhibiting no water-repellent/oil-repellent property.

After the irradiation, copolymer of poly(3,4)ethylenedioxythiophene and polystyrene sulfonate (PEDT-PSS) was formed into films as hole transport layers (103) by the spin coat method. Specifically, 500 ml of an aqueous solution of PEDT-PSS (0.5%) was dropped onto the substrate using a pipette, then the substrate was rotated at high speed (2000 rpm) to leave the PEDT-PSS solution in the ultraviolet light irradiated regions while removing the PEDT-PSS aqueous solution from the non-irradiated region (region where the PFPE1 thin film existed to exhibit a strong water-repellent/oil-repellent property), and was dried under 0.1 atmospheric pressure at 100° C. for one hour (film thickness 10 nm). When the film thickness of the PEDT-PSS layer exceeded 100 nm or was less than 1 nm, the luminous efficiency was extremely lowered to deviate from a practical range.

Thereafter, red high-molecular EL layers (104) were formed as films on the PEDT-PSS layers by the nozzle injection method. Specifically, 100 ml of a toluene solution of a red high-molecular EL material (0.5%) containing polyparaphenylenevinylene derivative was injected from minute-nozzles to be applied to the whole surface of the substrate, then the substrate was rotated at high speed (2000 rpm) to leave the EL solution on the PEDT-PSS layers while removing the EL solution from the ultraviolet light non-irradiated region, and was dried under normal pressure at 60° C. for one hour (film thickness 20 nm). When the film thickness of the EL layer exceeded 200 nm or was less than 1 nm, the luminous efficiency was extremely lowered to deviate from a practical range.

Incidentally, as an apparatus for injecting the high-molecular EL solution from the minute nozzles, use was made of an applying apparatus utilizing a printer head of an inkjet printer. However, upon injecting the EL solution, a control of injection and hitting position of the EL solution like that in the inkjet printer device was not executed so that the EL solution was applied to the whole surface of the substrate.

Then, formation of green light emitting layers was carried out in the following manner. PFPE1 was formed as a film on the whole surface of the substrate over the foregoing red light emitting layers under the same condition as described above. Then, using a photomask having openings (dimensions of an opening and a light shielding portion were the same as those of the foregoing photomask for red element formation) at positions, which will be green EL elements, in the lower electrode pattern, ultraviolet light was irradiated, under the same condition as described above, to the substrate at regions on the electrodes spaced apart from the red light emitting layers by 5 μm in a short-side direction thereof and 63.5 μm in a long-side direction thereof.

After the irradiation, PEDT-PSS layers were formed as films under the same condition as described above, then green high-molecular EL layers (105) containing spirofluorene derivative were formed as films under the same condition for the foregoing red EL layers.

Further, after this, PEDT-PSS layers and blue high-molecular EL layers (106) containing spirofluorene derivative were formed as films in regions on the electrodes between the green light emitting layers and the red light emitting layers, respectively.

Thereafter, the substrate was immersed in FC-77 at 50° C. for ten minutes to thereby dissolve and remove the PFPE1 films formed on the substrate and the red and green light emitting layers. Through this operation, the light emitting layers each including the PEDT-PSS layer in the form of the film and the film of the high-molecular EL material formed thereon were formed for three colors of red, green, and blue luminescence on the lower electrodes formed on the substrate. By forming as a film a cathode layer (107) made of an aluminum-lithium alloy (film thickness 100 nm) on the light emitting layers using the deposition method, electroluminescent bodies were produced.

The electroluminescent body thus produced achieved higher fineness (200 ppi, aperture ratio 50%) than the electroluminescent body produced by the deposition method or the inkjet method being the conventional method, and there was obtained the luminous efficiency about twice that of the electroluminescent body produced by the siloxane method. Further, with respect to the production cost of an electroluminescent display device having arrays of a large number of such electroluminescent bodies, it was largely reduced to ½ to ⅓ since a deposition apparatus or an inkjet apparatus was not used as in the conventional method and a large-sized substrate was able to be used.

### EXAMPLE 2

### An Electroluminescent Body Producing Method Using a Substrate with Pixel Regions Formed Flat, an Electroluminescent Body, and an Electroluminescent Display Device

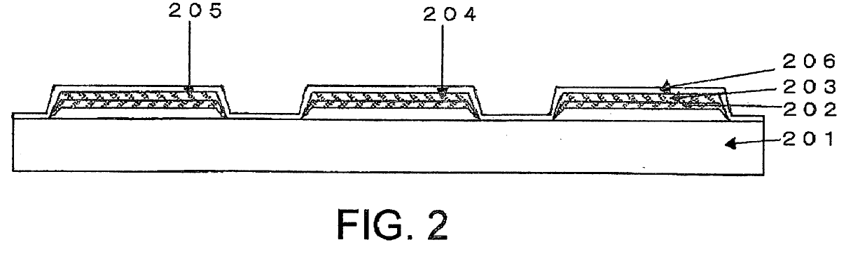

Description will be made referring to FIG. 2. Use was made of a substrate (201) equivalent to the glass substrate formed with the electrode pattern as recited in claim 1, and formation of red light emitting layers each (hole transport layer+EL layer) was carried out on a surface of the substrate in the following manner.

As a water-repellent/oil-repellent layer, HO—CH₂—(CF₂—CF₂—O)₈—(CF₂—O)₈—CH₂—OH (PFPE2) was formed into a film (film thickness 2 nm) by the dip method. Specifically, 2000 ml of a perfluorooctane solution of PFPE2 (0.02%) was put into a square glass container and, after fully immersing the substrate therein, it was drawn up at a constant speed (100 mm/min). This substrate was dried under normal pressure at 60° C. for 30 minutes (film thickness 2 nm). When the numbers of the CF₂—CF₂—O structures and the CF₂—O structures (values of p and q in General Formula 2) in a PFPE2 molecule both exceeded 8, the solubility thereof relative to the solvent such as perfluorooctane was extremely lowered so that an excellent water-repellent/oil-repellent layer could not be obtained. Using the same photomask as in Example 1, ultraviolet light having a center wavelength of 290 nm and a microwave having a wavelength of 12.2 cm (2450 MHz) were simultaneously (ultraviolet light 60 mW/cm², microwave 10 mW/cm²) irradiated to the substrate formed with the film of PFPE2 for three minutes. By simultaneously irradiating the ultraviolet light and the microwave, it was possible to shorten an irradiation time as compared with the case where only the ultraviolet light was irradiated. Then, PEDT-PSS layers (202) were formed as films by the print method in regions where the water-repellent/oil-repellent layer was eliminated by irradiation of the light. Specifically, a screen having a structure in which its portions corresponding to the light irradiated regions of the substrate were adapted to transmit ink therethrough, was tightly adhered to the substrate, then an aqueous solution of the PEDT-PSS layer (0.5%) was uniformly applied to the screen and dried under 0.5 atmospheric pressure at 200° C. for 30 minutes (film thickness 10 nm). Thereafter, red high-molecular EL layers (203) containing polyparaphenylenevinylene derivative were formed as films on the PEDT-PSS layers by the spray method.

Specifically, 100 ml of a p-xylene solution of an EL material (0.5%) was injected from spray nozzles in the form of spray to be applied to the whole surface of the substrate, then the substrate was rotated at high speed to remove the EL solution applied to the region other than the PEDT-PSS layers, and was dried under normal pressure at 60° C. for one hour (film thickness 20 nm). Thereafter, the substrate was immersed in perfluorooctane at 50° C. for ten minutes to thereby dissolve and remove the PFPE2 layer. Then, formation of green light emitting layers was carried out in the following manner. PFPE2 was formed into a film as a water-repellent/oil-repellent layer further over the foregoing red light emitting layers under the same condition as described above. Then, a photomask was disposed so as to match with regions where the green light emitting layers would be formed, and ultraviolet light and a microwave were irradiated under the same condition as in case of the foregoing red light emitting layers. After the irradiation, PEDT-PSS layers and green high-molecular EL layers (204) containing spirofluorene derivative were formed as films according to the same method for the foregoing red EL layers. Thereafter, the PFPE2 film was removed under the same condition as described above. Formation of blue light emitting layers was also carried out according to the same method for the foregoing green light emitting layers by the use of blue high-molecular EL layers (205) containing spirofluorene derivative. On these light emitting layers, a cathode layer (206) made of a silver-magnesium alloy was formed as a film by the print method. Specifically, a screen having a structure of transmitting ink to its region covering all the light emitting layers on the substrate was tightly adhered to the substrate, then a cathode ink in the form of paste obtained by adding an organic binder to fine powder of the silver-magnesium alloy was uniformly applied to the screen and kept under 0.1 atmospheric pressure at 200° C. for two hours to thereby form the cathode layer (film thickness 100 nm), so that electroluminescent bodies were produced.

The electroluminescent body thus produced achieved higher fineness (200 ppi, aperture ratio 50%) than the electroluminescent body produced by the deposition method or the inkjet method being the conventional method, and there was obtained the luminous efficiency about twice that of the electroluminescent body produced by the siloxane method. Further, with respect to the production cost of an electroluminescent display device having arrays of a large number of such electroluminescent bodies, it was largely reduced to ½ to ⅓ since a deposition apparatus or an inkjet apparatus was not used as in the conventional method and a large-sized substrate was able to be used.

### EXAMPLE 3

### An Electroluminescent Body Producing Method Using a Substrate with Pixel Regions Formed Concave, an Electroluminescent Body, and an Electroluminescent Display Device

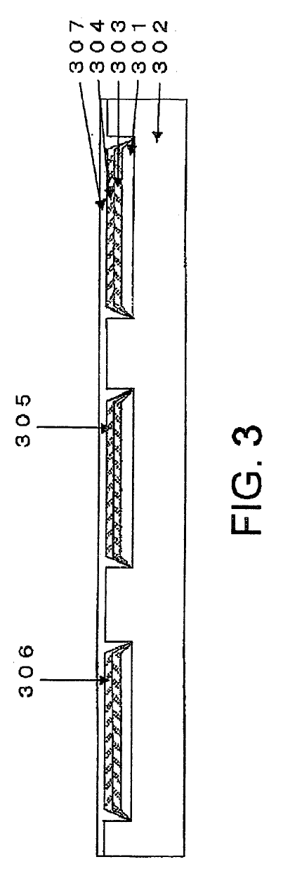

Description will be made referring to FIG. 3. Using a large-sized glass substrate (500 mm×500 mm, thickness 0.7 mm, 302 in FIG. 3) formed with circuits for driving active matrix EL elements, wherein regions of individual ITO lower electrodes (301) of a pattern arranged with a large number of the electrodes (electrode 61.0 μm×37.3 μm, an interval between the electrodes is 66.0 μm in a long-side direction of the electrode and 5 μm in a short-side direction thereof) were formed concave, formation of red light emitting layers was carried out in the following manner.

As a water-repellent/oil-repellent layer, F—(CF₂—CF₂—O)₈—COOH (PFPE3) was formed as a film (film thickness 2 nm) on the whole surface of the substrate by the deposition method. Specifically, PFPE3 (100 ml) was put into a magnetic crucible, then the glass substrate with its film forming surface facing downward was fixed at a position one meter above the crucible and kept for 30 minutes under the condition of 0.01 atmospheric pressure and 200° C. (film thickness 2 nm). When the number of the CF₂—CF₂—O structures (value of p in General Formula 3) in a PFPE3 molecule exceeded 8, an excellent water-repellent/oil-repellent layer could not be obtained. Using a photomask under the same condition as in Example 2, ultraviolet light and a microwave were simultaneously irradiated to the substrate formed with the film of PFPE3 for three minutes. PEDT-PSS layers (303) were formed as films by the dip method in regions where the water-repellent/oil-repellent layer was eliminated by the light irradiation. Specifically, 2000 ml of a PEDT-PSS aqueous solution (0.5%) was put into a square glass container and, after fully immersing the substrate therein, it was drawn up at a constant speed (100 mm/min). This substrate was dried under 0.5 atmospheric pressure at 200° C. for 30 minutes (film thickness 10 nm). Thereafter, red high-molecular EL layers (304) containing polyparaphenylenevinylene derivative were formed as films on the PEDT-PSS layers by the spin coat method. Specifically, 500 ml of a p-xylene solution of an EL material (0.5%) was dropped onto the substrate using a pipette, then the substrate was rotated at high speed (2000 rpm) to leave the EL solution in the ultraviolet light and microwave irradiated regions while removing the EL solution from the non-irradiated region, and was dried under normal pressure at 60° C. for 30 minutes (film thickness 20 nm). Thereafter, the substrate was immersed in perfluorooctane at 50° C. for ten minutes to thereby dissolve and remove the PFPE3 layer. Then, formation of green light emitting layers was carried out in the following manner. PFPE3 was formed into a film as a water-repellent/oil-repellent layer-further over the foregoing red light emitting layers under the same condition as described above. Then, a photomask was disposed so as to match with regions where the green light emitting layers would be formed, and ultraviolet light and a microwave were irradiated under the same condition as in case of the foregoing red light emitting layers. After the irradiation, PEDT-PSS layers and green high-molecular EL layers (305) containing spirofluorene derivative were formed as films (film thickness 20 nm) according to the same method for the foregoing red EL layers. Thereafter, the PFPE3 film was removed under the same condition as described above. Formation of blue light emitting layers was also carried out according to the same method for the foregoing green light emitting layers by the use of blue high-molecular EL layers (306) containing spirofluorene derivative. On these light emitting layers, a cathode layer (307) made of a silver-magnesium alloy was formed as a film by the print method. Specifically, a screen having a structure of transmitting ink to its region covering all the light emitting layers on the substrate was tightly adhered to the substrate, then a cathode ink in the form of paste obtained by adding an organic binder to fine powder of the silver-magnesium alloy was applied to the screen and kept under 0.01 atmospheric pressure at 200° C. for two hours to thereby form the cathode layer (film thickness 100 nm), so that electroluminescent bodies were produced.

The electroluminescent body thus produced achieved higher fineness (200 ppi, aperture ratio 50%) than the electroluminescent body produced by the deposition method or the inkjet method being the conventional method, and there was obtained the luminous efficiency about twice that of the electroluminescent body produced by the siloxane method. Further, with respect to the production cost of an electroluminescent display device having arrays of a large number of such electroluminescent bodies, it was largely reduced to ½ to ⅓ since a deposition apparatus or an inkjet apparatus was not used as in the conventional method and a large-sized substrate was able to be used.

### EXAMPLE 4

### An Electroluminescent Body Producing Method Using a Substrate with Outer Edge Portions of Pixel Regions Formed Convex, an Electroluminescent Body, and an Electroluminescent Display Device

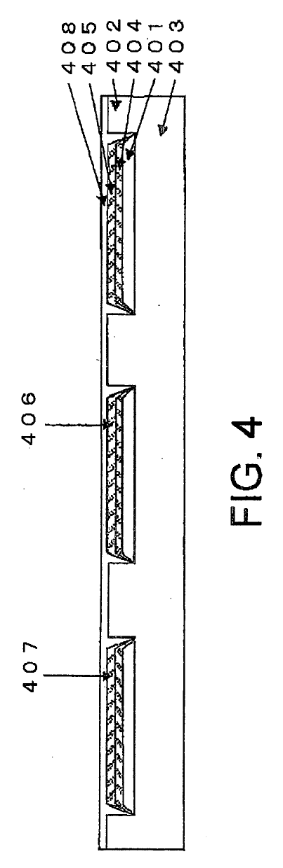

Description will be made referring to FIG. 4. On a large-sized glass substrate (500 mm×500 mm, thickness 0.7 mm, 403 in FIG. 4) with ITO lower electrodes that was formed with circuits for driving active matrix EL elements and that had a convex structure (402) along outer edge portions of individual ITO lower electrodes (401) in a pattern arranged with a large number of the electrodes (electrode 61.0 μm×37.3 μm, an interval between the electrodes is 66.0 μm in a long-side direction of the electrode and 5 μm in a short-side direction thereof), formation of red light emitting layers was carried out in the following manner.

As a water-repellent/oil-repellent layer, F—(CF(CF₃)—CF₂—O)₈—CF(CF₃)—COOH (PFPE4) was formed as a film on the substrate by the spin coat method. Specifically, 500 ml of a perfluorooctane solution of PFPE4 (0.01%) was dropped onto the substrate using a pipette, then the substrate was rotated at high speed (2000 rpm) and then heated to be dried under normal pressure at 100° C. for one hour. Ultraviolet light was irradiated to the substrate under the same condition and using the same photomask as in Example 1. After the irradiation, PEDT-PSS layers (404) were formed as films by the nozzle injection method. Specifically, 100 ml of an aqueous solution of PEDT-PSS (0.5%) was injected from minute nozzles to be applied to the whole surface of the substrate, then the substrate was rotated at high speed (2000 rpm) and dried under 0.1 atmospheric pressure at 60° C. for one hour (film thickness 10 nm). Thereafter, red high-molecular EL layers (405) containing polyparaphenylenevinylene derivative were formed as films (film thickness 20 nm) by the nozzle injection method like in Example 1. Thereafter, the substrate was immersed in perfluorooctane for ten minutes to thereby dissolve and remove the PFPE4 layer. Then, formation of green light emitting layers was carried out in the following manner. PFPE4 was formed into a film as a water-repellent/oil-repellent layer further over the red light emitting layers under the same condition as in the formation of the red light emitting layers. Then, a photomask was disposed so as to match with regions where the green light emitting layers would be formed, and ultraviolet light was irradiated under the same condition as described above. After the irradiation, PEDT-PSS layers were formed as films under the same condition as described above and then green high-molecular EL layers (406) containing spirofluorene derivative adapted to emit green light were formed as films (film thickness 20 nm) on the PEDT-PSS layers according to the same method for the foregoing red EL layers. Thereafter, the PFPE4 film was removed under the same condition as described above. Blue light emitting layers were also formed according to the same method for the foregoing green light emitting layers by forming as films blue high-molecular EL layers (407) containing spirofluorene derivative. On these light emitting layers, a cathode layer (408) made of a silver-magnesium alloy was formed as a film (film thickness 100 nm) by the deposition method like in Example 1, so that electroluminescent bodies were produced.

The electroluminescent body thus produced achieved higher fineness (200 ppi, aperture ratio 50%) than the electroluminescent body produced by the deposition method or the inkjet method being the conventional method, and there was obtained the luminous efficiency about twice that of the electroluminescent body produced by the siloxane method. Further, with respect to the production cost of an electroluminescent display device having arrays of a large number of such electroluminescent bodies, it was largely reduced to ½ to ⅓ since a deposition apparatus or an inkjet apparatus was not used as in the conventional method and a large-sized substrate was able to be used.

### 2. SECOND EMBODIMENT

The second embodiment of the present invention will be described.

A substrate of EL elements used in this embodiment has no limitation except that lower electrodes should be formable and, although a material thereof can be exemplified by glass, plastics, silicon, or the like, it is not limited to these examples. Further, with respect to the area and the thickness of the substrate, there is no limitation at all by this embodiment. With respect also to driving circuits, there is no limitation at all by this embodiment. Although a material of the lower electrode can be exemplified by In₂₋ₓSnₓO₃(ITO), In₂O₃, SnO₂, or the like, it is not limited to these examples. Further, with respect also to its film thickness, pattern shape, and surface roughness, there is no limitation at all by this embodiment. Although a material of a water-repellent/oil-repellent layer can be exemplified by compounds given by General Formulas 1 to 4 shown below, it is not limited to these examples.
G-CF₂—(CF₂)ₛ—CF₂-G General Formula 1
G-(CF₂—CF₂—O)ₚ—(CF₂—O)_{q}-G General Formula 2
G-(CF₂—CF₂—O)ᵣ-G General Formula 3
G-(CF(CF₃)—CF₂—O)ₚ—(CF(CF₃)—O)_{q}-G General Formula 4
In the formulas, G independently represents F, CH₂OH, COOH, NH₂ or a benzodioxol group. s represents an integer of 0 to 500. p and q independently represent integers of 0 to 100, respectively. r represents an integer of 1 to 200.

There is no particular limitation about the film thickness thereof. Further, there is no particular limitation about a film forming method of this water-repellent/oil-repellent layer and, although it can be exemplified by the spin coat method, the dip method, the deposition method, or the like, it is not limited to these examples.

Irradiation light is an electromagnetic wave having energy equal to or greater than energy corresponding to a bandgap of an optical semiconductor, and there is no limitation about its intensity, irradiation angle, irradiation time, and frequency. Further, such an electromagnetic wave and an electromagnetic wave having energy equal to or less than energy corresponding to the bandgap may be simultaneously irradiated.

A light emitting layer may be a monolayer or may have a stack structure composed of a hole transport layer, an organic EL layer, an electron transport layer, and the like, and there is no particular limitation about the kind of material forming each layer and the film thickness thereof.

Further, the kind of solvent for dissolving a material of the light emitting layer has no limitation except that it is other than one that dissolves the water-repellent/oil-repellent layer. Further, there is no particular limitation about the concentration of a solution thereof.

A film forming method of the light emitting layer can be exemplified by the spin coat method, the dip method, the spray method, the minute nozzle injection method, the print method, the transfer method, or the like, but is not limited to these examples. Further, the inkjet method can also be used.

A material of an upper electrode can be exemplified by an aluminum-lithium alloy, a silver-magnesium alloy, a silver-calcium alloy, or the like, but is not limited to these examples. The film thickness thereof also has no particular limitation and, although a film forming method thereof can be exemplified by the deposition method, the print method, or the like, it is not limited to these examples.

Hereinbelow, this embodiment will be described in further detail by examples.

### EXAMPLE 5

### A Patterning Method of Patterning Light Emitting Layers by the Dip Method and the Transfer Method, an Electroluminescent Body Producing Method, and an Electroluminescent Display Device

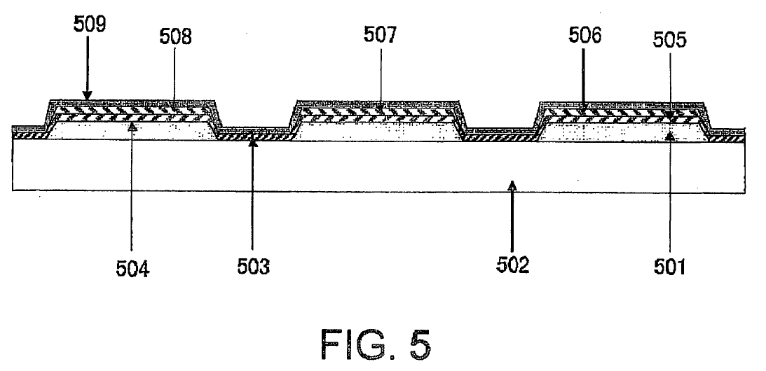

Description will be made referring to FIG. 5. On the whole surface of a glass substrate (502; 500 mm×500 mm, thickness 0.7 mm) formed with circuits for driving active matrix EL elements and with a lower electrode pattern arranged with a large number of ITO lower electrodes (501; 61.0 μm×37.3 μm, an interval between the electrodes is 66.0 μm in a long-side direction of the electrode and 5 μm in a short-side direction thereof, a water-repellent/oil-repellent material (FAS) G-CF₂—(CF₂)ₙ—CF₂-G (mixture where G=F and n=0 to 500) was formed into a film as a patterning layer (503; film thickness 2 nm) by the deposition method. When n of FAS exceeded 500, the film formability was deteriorated so that an excellent film could not be obtained.

UV light (70 mW/cm²) having a center wavelength of 290 nm was irradiated on the whole surface of the substrate from the FAS film side for five minutes. FAS on the ITO was decomposed to disappear so that the ITO surfaces were exposed (504).

After the irradiation, copolymer (PEDT-PSS) of poly(3,4)ethylenedioxythiophene and polystyrene sulfonate was formed into films as hole transport layers (505) by the dip method. Specifically, 500 ml of an aqueous solution of PEDT-PSS (1.0%) was put into a solution bath and the substrate was immersed therein, thereafter, the substrate was drawn up vertically at a speed of 10 mm/min. Since the PEDT-PSS solution was adhered to the substrate only in those regions where the ITO was exposed, it was dried under reduced pressure at 150° C. for one hour (film thickness 50 nm).

Thereafter, red high-molecular EL layers (506) were formed as films on the PEDT-PSS layers in the regions, which will be red EL elements, of the substrate by the transfer method. Specifically, a high-molecular EL material adapted to emit red light was formed as a film (film thickness 50 nm) on a plastic film having an absorption maximum at a wavelength of 830 nm, then the EL film surface of the plastic film was tightly adhered to the PEDT-PSS layer surfaces of the substrate, and laser light (830 nm, 10 mW) was irradiated to the PEDT-PSS layers from the plastic film side for 0.001 seconds per pixel to thereby transfer the EL film on the plastic film onto the PEDT-PSS layers.

The same operation was carried out with respect also to green high-molecular EL layers (507) and blue high-molecular EL layers (508), thereafter, the substrate was once put in a nitrogen atmosphere and then dried under reduced pressure at 80° C. for one hour (film thickness 50 nm). After drying, a cathode layer (509) made of a silver-calcium alloy was formed as a film (film thickness 100 nm) on those light emitting layers by the sputtering method so that electroluminescent bodies were produced.

The electroluminescent body thus produced enabled higher fineness (200 ppi, aperture ratio 50%) than the electroluminescent body produced by the deposition method or the inkjet method being the conventional method. Further, with respect to the production cost of an electroluminescent display device having arrays of a large number of such electroluminescent bodies, it was largely reduced since a deposition apparatus or an inkjet apparatus was not used as in the conventional method and a large-sized substrate was able to be used.

### EXAMPLE 6

### A Patterning Method of Patterning Light Emitting Layers by the Minute Nozzle Injection Method, an Electroluminescent Body Producing Method, and an Electroluminescent Display Device

On the whole surface of a glass substrate 502 having ITO lower electrodes 501, which were the same as those in Example 5, a water-repellent/oil-repellent material (FAS) G-(CF₂—CF₂—O)ₚ—(CF₂—O)_{q}-G (mixture where G=CH₂OH, p=0 to 100, and q=0 to 100) was formed into a film as a patterning layer by the spin coat method. Specifically, 20 ml of a perfluorooctane solution of FAS (0.024%) was dropped onto the substrate using a pipette, then the substrate was rotated at high speed (1000 rpm) and dried at 100° C. for one hour (film thickness 2 nm). When p and q of FAS exceeded 100, the film formability was deteriorated so that an excellent film could not be obtained.

UV light (70 mW/cm²) having a center wavelength of 340 nm was irradiated on the whole surface of the substrate from the FAS film side for 30 minutes. FAS on the ITO was decomposed to disappear so that the ITO surfaces were exposed.

After the irradiation, copolymer (PEDT-PSS) of poly(3,4)ethylenedioxythiophene and polystyrene sulfonate was formed into films (503) as hole transport layers by the minute nozzle injection method. Specifically, an aqueous solution of PEDT-PSS (1.0%) was injected from minute nozzles to be applied to the exposed portions of the ITO electrodes, then dried under reduced pressure at 150° C. for one hour (film thickness 50 nm). Incidentally, an apparatus used in the minute nozzle injection method was produced by utilizing a printer head of an inkjet printer. Upon the injection, however, a precise control of hitting positions of droplets like that in the inkjet printer device was not executed so that the solution was hit around the application regions.

Thereafter, red high-molecular EL layers 504 were formed as films by the minute nozzle injection method. Specifically, a tetralin solution of a red high-molecular EL material (1.0%) was injected from minute nozzles to be applied to the PEDT-PSS layers in those regions that would be red EL elements. After performing the same operation with respect also to green high-molecular EL layers 505 and blue high-molecular EL layers 506, the substrate was once put in a nitrogen atmosphere and then dried under reduced pressure at 80° C. for one hour (film thickness 50 nm). After drying, a magnesium-silver alloy was formed as a film (film thickness 100 nm) on those light emitting layers by the deposition method to form a cathode 507 so that electroluminescent bodies were produced.

Along with the method shown in the foregoing example, with respect also to a case using, as FAS, G-(CF₂—CF₂—O)ₚ—(CF₂—O)_{q}-G (mixture where G=benzodioxol group, p=0 to 100, and q=0 to 100), the same operation was carried out subsequently to thereby produce electroluminescent bodies.

The electroluminescent body thus produced enabled higher fineness (200 ppi, aperture ratio 50%) than the electroluminescent body produced by the deposition method or the inkjet method being the conventional method. Further, with respect to the production cost of an electroluminescent display device having arrays of a large number of such electroluminescent bodies, it was largely reduced since a deposition apparatus or an inkjet apparatus was not used as in the conventional method and a large-sized substrate was able to be used.

### EXAMPLE 7

### A Patterning Method of Patterning Light Emitting Layers by the Spray Method and the Print Method, an Electroluminescent Body Producing Method, and an Electroluminescent Display Device

On the whole surface of a glass substrate 502 having ITO lower electrodes 501, which were the same as those in Example 5, a water-repellent/oil-repellent material (FAS) G-(CF₂—CF₂—O)ᵣ-G (mixture where G=COOH and r=1 to 200) was formed into a film as a patterning layer by the spin coat method.

Specifically, 20 ml of a perfluorooctane solution of FAS (0.024%) was dropped onto the substrate using a pipette, then the substrate was rotated at high speed (1000 rpm) and dried at 100° C. for one hour (film thickness 2 nm). When r of FAS exceeded 200, the film formability was deteriorated so that, an excellent film could not be obtained.

UV light (70 mW cm²) having a center wavelength of 340 nm was irradiated on the whole surface of the substrate from the FAS film side for 15 minutes. FAS on the ITO was decomposed to disappear so that the ITO surfaces were exposed. After the irradiation, copolymer (PEDT-PSS) of poly(3,4)ethylenedioxythiophene and polystyrene sulfonate was formed into films (503) as hole transport layers by the spray method. Specifically, an aqueous solution of PEDT-PSS (1.0%) was injected from spray nozzles in the form of spray to be applied to the whole surface of the substrate, then the substrate was rotated at high speed to remove the PEDT-PSS aqueous solution applied to the region other than the ITO exposed regions, and was dried at 150° C. for one hour (film thickness 50 nm).

Thereafter, high-molecular EL layers were formed as films by the print method. Specifically, a high-molecular EL material was dissolved in tetramethylbenzene (5.5%) to obtain an EL ink, then a screen adapted to transmit the EL ink only for those regions that would be red elements was applied to the substrate and the red EL ink was applied to the screen. This substrate was once put in a nitrogen atmosphere and then dried under reduced pressure at 100° C. for two hours (film thickness 50 nm). Similarly, a green EL ink and a blue EL ink were applied to predetermined regions and dried so that R, G, and B light emitting layers were formed (504, 505, 506). A lithium-aluminum alloy was formed as a film (film thickness 100 nm) on these light emitting layers by the deposition method to form a cathode 507 so that electroluminescent bodies were produced.

Along with the method shown in the foregoing example, with respect also to a case using, as FAS, G-(CF(CF₃)—CF₂—O)ₚ—(CF(CF₃)—O)_{q}-G (mixture where G=NH₂, p=0 to 100, and q=0 to 100), the same operation was carried out subsequently to thereby produce electroluminescent bodies.

The electroluminescent body thus produced enabled higher fineness (200 ppi, aperture ratio 50%) than the electroluminescent body produced by the deposition method or the inkjet method being the conventional method. Further, with respect to the production cost of an electroluminescent display device having arrays of a large number of such electroluminescent bodies, it was largely reduced since a deposition apparatus or an inkjet apparatus was not used as in the conventional method and a large-sized substrate was able to be used.

### EXAMPLE 8

### A Patterning Method of Patterning Light Emitting Layers by the Dip Method and the Transfer Method, an Electroluminescent Body Producing Method, and an Electroluminescent Display Device

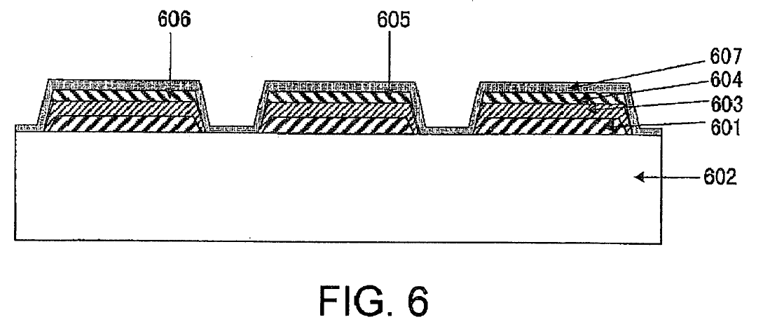

Description will be made referring to FIG. 6. On a large-sized glass substrate 602 formed with a pattern that was arranged with a large number of ITO lower electrodes 601 like those in Example 5, formation of red light emitting layers was first carried out in the following manner.

On the substrate including the ITO electrodes, G-(CF(CF₃)—CF₂—O)ₚ—(CF(CF₃)—O)_{q}-G (mixture where G=CH₂OH, p=0 to 100, and q=0 to 100) was formed into a film as a water-repellent/oil-repellent layer (FAS) by the spin coat method under the same condition as in Example 6. When p and q of FAS exceeded 100, the film formability was deteriorated so that an excellent film could not be obtained.

Using a photomask for red light emitting layer formation, light beam (70 mW/cm²) in an ultraviolet-visible region having a center wavelength of 290 nm and a long wavelength end of 400 nm was irradiated to the substrate formed with the film of FAS for five minutes.

Then, PEDT-PSS layers 603 were formed as films by the dip method in those regions irradiated with the light. Specifically, 100 ml of an aqueous solution of PEDT-PSS (0.5%) was put into a solution bath and the substrate was immersed therein, thereafter, the substrate was drawn up vertically at a speed of 10 mm/min. This substrate was rotated at high speed and then dried under the same condition as in Example 5 (film thickness 10 nm).

Thereafter, red high-molecular EL layers (604) were formed as films on the PEDT-PSS layers by the transfer method. Specifically, a high-molecular EL material adapted to emit red light was formed as a film (film thickness 20 nm) on a plastic film having an absorption maximum at a wavelength of 830 nm, then the EL film surface of the plastic film was tightly adhered to the PEDT-PSS layer surfaces of the substrate, and laser light (830 nm, 10 mW) was irradiated to the regions formed with the PEDT-PSS layers from the plastic film side for 0.001 seconds to thereby transfer the EL film on the plastic film onto the PEDT-PSS layers, and then the substrate was dried at 60° C. for one hour (film thickness 20 nm). Thereafter, the substrate was washed for ten minutes while keeping the whole surface of the substrate in contact with perfluorooctane, to thereby remove the FAS layer.

Then, formation of green light emitting layers was carried out in the following manner. FAS was formed into a film as a water-repellent oil-repellent layer further over the foregoing red light emitting layers under the same condition as described above and, using a photomask for green element formation, ultraviolet-visible light was irradiated to the substrate under the same condition as described above. After the irradiation, PEDT-PSS layers were formed as films under the same condition as described above, then green high-molecular EL layers 605 were formed as films (film thickness 20 nm) on the PEDT-PSS layers by the transfer method like the red EL layers. Thereafter, the substrate was washed for ten minutes while contacting with perfluorooctane under the same condition as described above, to thereby remove the FAS layer on the substrate and the red light emitting layers.

Thereafter, further, blue light emitting layers each comprising a PEDT-PSS layer and a blue high-molecular EL layer 606 were formed like the foregoing red light emitting layers and green light emitting layers. A cathode layer 607 made of a silver-calcium alloy was formed as a film (film thickness 100 nm) on those light emitting layers by the sputtering method so that electroluminescent bodies were produced.

The electroluminescent body thus produced enabled higher fineness (200 ppi, aperture ratio 50%) than the electroluminescent body produced by the deposition method or the inkjet method being the conventional method. Further, with respect to the production cost of an electroluminescent display device having arrays of a large number of such electroluminescent bodies, it was largely reduced since a deposition apparatus or an inkjet apparatus was not used as in the conventional method and a large-sized substrate was able to be used.

### EXAMPLE 9

### A Patterning Method of Patterning Light Emitting Layers by the Dip Method and the Transfer Method, an Electroluminescent Body Producing Method, and an Electroluminescent Display Device

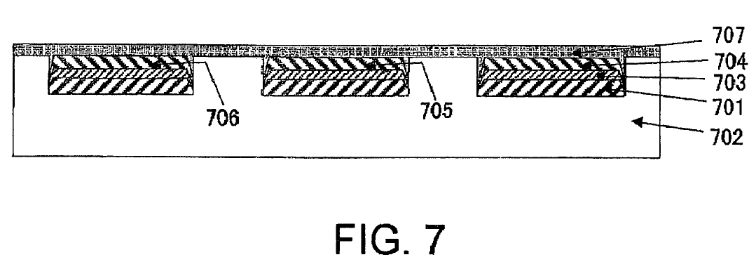

Description will be made referring to FIG. 7. On a large-sized glass substrate 702 formed with circuits for driving active matrix EL elements, wherein regions of individual ITO lower electrodes 701 of a pattern arranged with a large number of the electrodes (electrode 61.0 μm×37.3 μm, an interval between the electrodes is 66.0 μm in a long-side direction of the electrode and 5 μm in a short-side direction thereof) were formed concave, formation of red light emitting layers was carried out in the following manner.

First, G-(CF₂—CF₂—O)ₚ—(CF₂—O)_{q}-G (mixture where G=COOH, p=0 to 100, and q=0 to 100) was formed into a film as a water-repellent/oil-repellent layer (FAS) by the spin coat method. Specifically, 5 ml of a perfluorooctane solution of FAS (0.01 %) was dropped onto the substrate using a pipette, then the substrate was rotated at high speed (1000 rpm) and dried at 60° C. for one hour (film thickness 2 nm).

Ultraviolet light and a microwave were irradiated via a photomask to positions, which would be red EL elements, in the lower electrode pattern of the substrate formed with the film of FAS like in Example 8, then PEDT-PSS layers 703 and red high-molecular EL layers 704 were formed as films according to the same methods as in Example 8 to thereby form red light emitting layers. Thereafter, FAS was removed by the same method as in Example 8.

Green light emitting layers 705 and blue light emitting layers 706 were also formed by the same method as in Example 4, and further, a cathode layer 707 was also formed as a film (film thickness 100 nm) by the same method as in Example 8 so that electroluminescent bodies were produced.

The electroluminescent body thus produced enabled higher fineness (200 ppi, aperture ratio 50%) than the electroluminescent body produced by the deposition method or the inkjet method being the conventional method. Further, with respect to the production cost of an electroluminescent display device having arrays of a large number of such electroluminescent bodies, it was largely reduced since a deposition apparatus or an inkjet apparatus was not used as in the conventional method and a large-sized substrate was able to be used.

### EXAMPLE 10

### A Patterning Method of Patterning Light Emitting Layers by the Dip Method and the Transfer Method, an Electroluminescent Body Producing Method, and an Electroluminescent Display Device

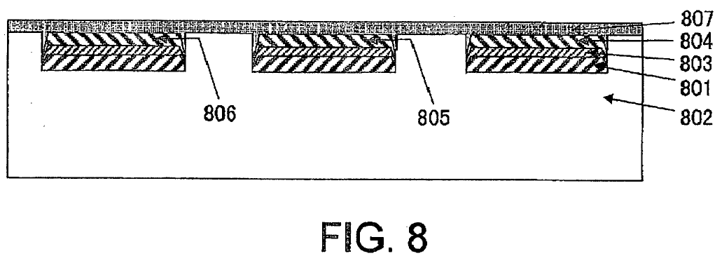

Description will be made referring to FIG. 8. On a glass substrate with ITO lower electrodes that was formed with circuits for driving active matrix EL elements and that had a convex structure (802) along outer edge portions of individual ITO lower electrodes (801) in a pattern arranged with a large number of the electrodes (electrode 61.0 μm×37.3 μm, an interval between the electrodes is 66.0 μm in a long-side direction of the electrode and 5 μm in a short-side direction thereof), formation of red light emitting layers was carried out according to the following method.

G-(CF₂—CF₂—O)ᵣ-G (mixture where G=CH₂OH and r=1 to 200) was formed into a film as a water-repellent/oil-repellent layer (FAS) on the substrate by the spin coat method. Specifically, 5 ml of a perfluorooctane solution of FAS (0.01%) was dropped onto the substrate using a pipette, then the substrate was rotated at high speed (1000 rpm) and heated to be dried at 100° C. for one hour (film thickness 2 nm). Ultraviolet light and a microwave were irradiated via a photomask to positions, which would be red light emitting layers, in the lower electrode pattern of the substrate formed with the film of FAS under the same condition as in Example 9, then PEDT-PSS layers (803) and red high-molecular EL layers (804) were formed as films according to the same methods as in Example 9 to thereby form red light emitting layers. Thereafter, FAS was removed by the same method as in Example 9. Green light emitting layers (805) and blue light emitting layers (806) were also formed by the same method as in Example 9, and further, a cathode layer (807) was also formed as a film (film thickness 100 nm) by the same method as in Example 9 so that electroluminescent bodies were produced.

The electroluminescent body thus produced enabled higher fineness (200 ppi, aperture ratio 50%) than the electroluminescent body produced by the deposition method or the inkjet method being the conventional method. Further, with respect to the production cost of an electroluminescent display device having arrays of a large number of such electroluminescent bodies, it was largely reduced since a deposition apparatus or an inkjet apparatus was not used as in the conventional method and a large-sized substrate was able to be used.

Although the present invention has been described above based on the embodiments and examples thereof, it is readily understood that the present invention is not limited thereto and may be changed or improved within the range of normal knowledge of a person skilled in the art.

Industrial Applicability

As described above, according to the electroluminescent body producing method of the present invention that performs patterning of light emitting layers using a water-repellent/oil-repellent layer which does not include a photocatalyst layer or generate a solid decomposition product, it is possible to produce an electroluminescent body and an electroluminescent display device with higher fineness, with higher efficiency,.and at a lower cost as compared with the conventional deposition method, inkjet method or siloxane method.

Further, according to the patterning method or the electroluminescent body producing method of the present invention that performs patterning of light emitting layers in regions that lost a water-repellent/oil-repellent property, it is possible to produce an electroluminescent body and an electroluminescent display device with higher fineness and at a lower cost as compared with the conventional deposition method or inkjet method.

1. A method of producing an electroluminescent body in which a lower electrode pattern is formed on a substrate, a light emitting layer including at least one of a hole transport layer and an electron transport layer, and an organic EL layer is formed on said lower electrode pattern, an upper electrode is formed on said light emitting layer, and at least one of said lower electrode and said upper-electrode is transparent, said method characterized by comprising:
a step 1 of forming a water-repellent/oil-repellent layer, which is decomposed to disappear by light irradiation, on said substrate formed with at least said lower electrode pattern;
a step 2 of irradiating light to a region A including a portion, corresponding to said lower electrode pattern, on said water-repellent/oil-repellent layer to eliminate said water-repellent/oil-repellent layer in said region A;
a step 3 of forming said light emitting layer in said region A; and
a step 4 of forming said upper electrode on said light emitting layer.

2. An electroluminescent body producing method according to claim 1, characterized in that the light irradiated to said region A in said step 1 is one of ultraviolet light and an electromagnetic wave including ultraviolet light and a microwave.

3. An electroluminescent body producing method according to claim 1, characterized in that said step 3 includes at least one kind of a spin coat method, a dip method, a spray method, a nozzle injection method, a print method, and a transfer method.

4. An electroluminescent body producing method according to claim 1, characterized in that said step 3 comprises a step of holding in an environment of no less than 60° C. and no more than a normal pressure for no less than ten seconds for removing a solvent from said formed light emitting layer and drying.

5. An electroluminescent body producing method according to claim 1, characterized in that said step 4 includes at least one kind of a deposition method, a sputtering method, an application method, and a print method.

6. An electroluminescent body formed with, on a substrate, a lower electrode pattern, a light emitting layer including at least one of a hole transport layer and an electron transport layer, and an organic EL layer, and an upper electrode, at least one of said lower electrode and said upper electrode being transparent, said electroluminescent body characterized by comprising:
a concave region formed concave and including a portion corresponding to said lower electrode pattern;
a water-repellent/oil-repellent layer formed outside said concave region; and
said light emitting layer formed in said concave region.

7. An electroluminescent display device characterized by comprising the electroluminescent body according to claim 6.

8. An electroluminescent body formed with, on a substrate, a lower electrode pattern, a light emitting layer including at least one of a hole transport layer and an electron transport layer, and an organic EL layer, and an upper electrode, at least one of said lower electrode and said upper electrode being transparent, said electroluminescent body characterized by comprising:
a convex region formed in a region corresponding to an outer edge portion of said lower electrode pattern;
a water-repellent/oil-repellent layer formed at an upper edge portion of said convex region and outside said convex region; and
said light emitting layer formed inside said convex region.

9. An electroluminescent display device characterized by comprising the electroluminescent body according to claim 8.

10. An electroluminescent body formed with, on a substrate, a lower electrode pattern, a light emitting layer including at least one of a hole transport layer and an electron transport layer, and an organic EL layer, and an upper electrode, at least one of said lower electrode and said upper electrode being transparent, said electroluminescent body characterized by comprising:
the light emitting layer formed in a region A corresponding to said lower electrode pattern;
a water-repellent/oil-repellent layer formed outside said region A; and
the upper electrode formed in a region including a portion on said light emitting layer.

11. An electroluminescent body according to claim 10, characterized in that a photocatalyst layer is not formed on said lower electrode pattern.

12. An electroluminescent body according to claim 10, characterized in that said water-repellent/oil-repellent layer or a substance produced by a chemical change of said water-repellent/oil-repellent layer is not formed in said region A.

13. An electroluminescent body according to claim 10, characterized in that said lower electrode includes at least one kind of component of indium oxide, tin oxide, and zinc oxide.

14. An electroluminescent body according to claim 10, characterized in that, given that n represents an integer of 1 to 18, G independently represents one of F, CH₂—OH, and COOH, and p and q independently represent integers of 1 to 8, respectively, said water-repellent/oil-repellent layer includes one of compounds identified by the following General Formulas 1 to 4:
G-(CF₂)ₙ-G General Formula 1
G-(CF₂—CF₂—O)ₚ—(CF₂—O)_{q}-G General Formula 2
G-(CF₂—CF₂—O)ₚ-G General Formula 3
G-(CF(CF₃)—CF₂—O)ₚ—CF(CF₃)-G. General Formula 4

15. An electroluminescent body according to claim 10, characterized in that a film thickness of said water-repellent/oil-repellent layer falls within a range of 100 μm to 0.1 nm.

16. An electroluminescent body according to claim 10, characterized in that the hole transport layer in said light emitting layer is made of a conductive high-molecular compound containing copolymer of poly(3,4)ethylenedioxythiophene and polystyrene sulfonate.

17. An electroluminescent body according to claim 10, characterized in that a film thickness of the hole transport layer in said light emitting layer falls within a range of 100 nm to 1 nm.

18. An electroluminescent body according to claim 10, characterized in that said organic EL layer includes one of a high-molecular compound containing a polyparaphenylenevinylene skeleton and a high-molecular compound containing a spirofluorene skeleton.

19. An electroluminescent body according to claim 10, characterized in that a film thickness of said organic EL layer falls within a range of 200 nm to 1 nm.

20. An electroluminescent display device characterized by comprising the electroluminescent body according to claim 10.

21. A patterning method characterized by providing, on a substrate, a patterning layer having a surface leakage property relative to a stacking material which is different from that of the substrate, and forming a pattern of said stacking material by partly eliminating said patterning layer and utilizing a difference in surface leakage property between an exposed portion of the substrate and the patterning layer.

22. A patterning method according to claim 18, characterized in that a material forming the patterning layer having the surface leakage property relative to the stacking material different from that of the substrate comprises a compound that produces only a gaseous decomposed substance when photodecomposed by a semiconductor photocatalyst.

23. A patterning method according to claim 21, characterized in that the patterning layer is a water-repellent/oil-repellent layer and the water-repellent/oil-repellent layer contains one of compounds identified by the following General Formulas 1 to 4:
G-CF₂—(CF₂)ₛ—CF₂-G General Formula 1
G-(CF₂—CF₂—O)ₚ—(CF₂—O)_{q}-G General Formula 2
G-(CF₂—CF₂—O)ᵣ-G General Formula 3
G-(CF(CF₃)—CF₂—O)ₚ—(CF(CF₃)—O)_{q}-G General Formula 4
where G independently represents F, CH₂—OH, COOH, NH₂ or a benzodioxol group, s represents an integer of 0 to 500, p and q independently represent integers of 0 to 100, respectively, and r represents an integer of 1 to 200.

24. A patterning method characterized by comprising:
a step of providing a patterning layer on a substrate formed with a pattern made of a material containing at least a semiconductor photocatalyst, said patterning layer having a surface leakage property relative to a stacking material which is different from that of a surface of said pattern;
a step of irradiating an electromagnetic wave including an energy component equal to or greater than a bandgap of the semiconductor photocatalyst, to the whole surface of the substrate or a region including said pattern for photodecomposing and eliminating the patterning layer on said pattern; and
a step of forming a pattern of said stacking material utilizing a difference in surface leakage property between the patterning layer and the surface of said pattern.

25. A patterning method according to claim 24, characterized in that a photomask for forming a non-irradiated region on the substrate is not used upon irradiating the electromagnetic wave including the energy component equal to or greater than the bandgap of the semiconductor photocatalyst, to the whole surface of the substrate or the region including the pattern made of the material containing the semiconductor photocatalyst.

26. A patterning method according to claim 24, characterized in that the patterning layer is a water-repellent/oil-repellent layer and the water-repellent/oil-repellent layer contains one of compounds identified by the following General Formulas 1 to 4:
G-CF₂—(CF₂)ₛ—CF₂-G General Formula 1
G-(CF₂—CF₂—O)ₚ—(CF₂—O)_{q}-G General Formula 2
G-(CF₂—CF₂—O)ᵣ-G General Formula 3
G-(CF(CF₃)—CF₂—O)ₚ—(CF(CF₃)—O)_{q}-G General Formula 4
where G independently represents F, CH₂—OH, COOH, NH₂ or a benzodioxol group, s represents an integer of 0 to 500, p and q independently represent integers of 0 to 100, respectively, and r represents an integer of 1 to 200.

27. A patterning method according to claim 24, characterized in that the patterning layer is a water-repellent/oil-repellent layer, and light irradiated to a region including a portion, corresponding to a lower electrode pattern, on the water-repellent/oil-repellent layer is ultraviolet light, ultraviolet light and visible light, or an electromagnetic wave including ultraviolet light and a microwave.

28. A method of producing an electroluminescent body in which a lower electrode pattern is formed on a substrate, a light emitting layer is formed on the lower electrode pattern, an upper electrode is formed on the light emitting layer, and at least one of the lower electrode and the upper electrode is transparent, said method characterized by comprising:
a step of providing a patterning layer on the substrate formed with said lower electrode pattern;
a step of irradiating an electromagnetic wave including ultraviolet light to the whole surface of the substrate provided with the patterning layer or a region including the lower electrode pattern;
a step of stacking at least the light emitting layer on the lower electrode where the patterning layer is eliminated; and
a step of forming the upper electrode in a region including an upper surface of the light emitting layer.

29. An electroluminescent body producing method according to claim 28, characterized in that the patterning layer is a water-repellent/oil-repellent layer and the water-repellent/oil-repellent layer contains one of compounds identified by the following General Formulas 1 to 4:
G-CF₂—(CF₂)ₛ—CF₂-G General Formula 1
G-(CF₂—CF₂—O)ₚ—(CF₂—O)_{q}-G General Formula 2
G-(CF₂—CF₂—O)ᵣ-G General Formula 3
G-(CF(CF₃)—CF₂—O)ₚ—(CF(CF₃)—O)_{q}-G General Formula 4
where G independently represents F, CH₂—OH, COOH, NH₂ or a benzodioxol group, s represents an integer of 0 to 500, p and q independently represent integers of 0 to 100, respectively, and r represents an integer of 1 to 200.

30. An electroluminescent body producing method according to claim 28, characterized in that the patterning layer is a water-repellent/oil-repellent layer, and light irradiated to a region including a portion, corresponding to the lower electrode pattern, on the water-repellent/oil-repellent layer is ultraviolet light, ultraviolet light and visible light, or an electromagnetic wave including ultraviolet light and a microwave.

31. An electroluminescent body producing method according to claim 28, characterized in that the patterning layer is a water-repellent/oil-repellent layer, and a method of forming the light emitting layer in a region where a water-repellent/oil-repellent property is lost includes at least one kind of method in a spin coat method, a dip method, a spray method, a minute nozzle injection method, a print method, and a transfer method.

32. An electroluminescent body producing method according to claim 28, characterized in that the patterning layer is a water-repellent/oil-repellent layer and, after forming the light emitting layer, the water-repellent/oil-repellent layer is removed from the substrate by immersing the substrate in an organic solvent having a property of dissolving the water-repellent/oil-repellent layer.

33. An electroluminescent body producing method according to claim 28, characterized in that the patterning layer is a water-repellent/oil-repellent layer and, after forming the light emitting layer, the water-repellent/oil-repellent layer is removed from the substrate by contacting the water-repellent/oil-repellent layer on the substrate with an organic solvent having a property of dissolving the water-repellent/oil-repellent layer.

34. An electroluminescent body producing method according to claim 28, characterized in that a method of forming the upper electrode on the formed light emitting layer includes at least one kind of method in a deposition method, a sputtering method, and a print method.

35. An electroluminescent body producing method according to claim 28, characterized in that one or both of the lower electrode forming the pattern and the upper electrode contain at least one kind of titanium oxide, indium oxide, tin oxide, and indium-tin composite oxide (ITO).

36. A method of producing an electroluminescent body in which a lower electrode pattern is formed on a substrate, a light emitting layer is formed on the lower electrode pattern, an upper electrode is formed on the light emitting layer, and at least one of the lower electrode and the upper electrode is transparent, said method characterized by comprising:
a step of forming a water-repellent/oil-repellent layer on the substrate formed with at least the lower electrode pattern;
a step of irradiating light to a region including a portion, corresponding to the lower electrode pattern, on the water-repellent/oil-repellent layer to cause a water-repellent/oil-repellent property on the lower electrode pattern to be lost;
a step of forming the light emitting layer in the region where the water-repellent/oil-repellent property is lost; and
a step of forming the upper electrode on the formed light emitting layer.

37. An electroluminescent body producing method according to claim 36, characterized in that the patterning layer is a water-repellent/oil-repellent layer and the water-repellent/oil-repellent layer contains one of compounds identified by the following General Formulas 1 to 4:
G-CF₂—(CF₂)ₛ—CF₂-G General Formula 1
G-(CF₂—CF₂—O)ₚ—(CF₂—O)_{q}-G General Formula 2
G-(CF₂—CF₂—O)ᵣ-G General Formula 3
G-(CF(CF₃)—CF₂—O)ₚ—(CF(CF₃)—O)_{q}-G General Formula 4
where G independently represents F, CH₂—OH, COOH, NH₂ or a benzodioxol group, s represents an integer of 0 to 500, p and q independently represent integers of 0 to 100, respectively, and r represents an integer of 1 to 200.

38. An electroluminescent body producing method according to claim 36, characterized in that the patterning layer is a water-repellent/oil-repellent layer, and light irradiated to a region including a portion, corresponding to the lower electrode pattern, on the water-repellent/oil-repellent layer is ultraviolet light, ultraviolet light and visible light, or an electromagnetic wave including ultraviolet light and a microwave.

39. An electroluminescent body producing method according to claim 36, characterized in that the patterning layer is a water-repellent/oil-repellent layer, and a method of forming the light emitting layer in a region where a water-repellent/oil-repellent property is lost includes at least one kind of method in a spin coat method, a dip method, a spray method, a minute nozzle injection method, a print method, and a transfer method.

40. An electroluminescent body producing method according to claim 36, characterized in that the patterning layer is a water-repellent/oil-repellent layer and, after forming the light emitting layer, the water-repellent/oil-repellent layer is removed from the substrate by immersing the substrate in an organic solvent having a property of dissolving the water-repellent/oil-repellent layer.

41. An electroluminescent body producing method according to claim 36, characterized in that the patterning layer is a water-repellent/oil-repellent layer and, after forming the light emitting layer, the water-repellent/oil-repellent layer is removed from the substrate by contacting the water-repellent/oil-repellent layer on the substrate with an organic solvent having a property of dissolving the water-repellent/oil-repellent layer.

42. An electroluminescent body producing method according to claim 36, characterized in that a method of forming the upper electrode on the formed light emitting layer includes at least one kind of method in a deposition method, a sputtering method, and a print method.

43. An electroluminescent body producing method according to claim 36, characterized in that one or both of the lower electrode forming the pattern and the upper electrode contain at least one kind of titanium oxide, indium oxide, tin oxide, and indium-tin composite oxide (ITO).

44. An electroluminescent body in which a lower electrode pattern is formed on a substrate, a light emitting layer is formed on the lower electrode pattern, an upper electrode is formed on the light emitting layer, and at least one of the lower electrode and the upper electrode is transparent, said electroluminescent body characterized by having a structure in which no partition exists between adjacent light emitting layers.

45. An electroluminescent body according to claim 44, characterized in that one or both of the lower electrode forming the pattern and the upper electrode contain at least one kind of titanium oxide, indium oxide, tin oxide, and indium-tin composite oxide (ITO).

46. An electroluminescent display device characterized by comprising the electroluminescent body according to claim 44.

47. An electroluminescent body in which a lower electrode pattern is formed on a substrate, a light emitting layer is formed on the lower electrode pattern, an upper electrode is formed on the light emitting layer, and at least one of the lower electrode and the upper electrode is transparent, said electroluminescent body characterized by having a structure in which the light emitting layer is not formed inside a hole.

48. An electroluminescent body according to claim 47, characterized in that one or both of the lower electrode forming the pattern and the upper electrode contain at least one kind of titanium oxide, indium oxide, tin oxide, and indium-tin composite oxide (ITO).

49. An electroluminescent display device characterized by comprising the electroluminescent body according to claim 47.

50. An electroluminescent body in which a lower electrode pattern is formed on a substrate, a light emitting layer is formed on the lower electrode pattern, an upper electrode is formed on the light emitting layer, and at least one of the lower electrode and the upper electrode is transparent, said electroluminescent body characterized by having a structure in which a patterning layer is formed in a region on the substrate where the lower electrode does not exist, while is not formed on the lower electrode.

51. An electroluminescent body according to claim 50, characterized in that one or both of the lower electrode forming the pattern and the upper electrode contain at least one kind of titanium oxide, indium oxide, tin oxide, and indium-tin composite oxide (ITO).

52. An electroluminescent body according to claim 50, characterized in that a water-repellent/oil-repellent layer used as the patterning layer contains one of compounds identified by the following General Formulas 1 to 4:
G-CF₂—(CF₂)ₛ—CF₂-G General Formula 1
G-(CF₂—CF₂—O)ₚ—(CF₂—O)_{q}-G General Formula 2
G-(CF₂—CF₂—O)ᵣ-G General Formula 3
G-(CF(CF₃)—CF₂—O)ₚ—(CF(CF₃)—O)_{q}-G General Formula 4
where G independently represents F, CH₂—OH, COOH, NH₂ or a benzodioxol group, s represents an integer of 0 to 500, p and q independently represent integers of 0 to 100, respectively, and r represents an integer of 1 to 200.

53. An electroluminescent display device characterized by comprising the electroluminescent body according to claim 50.

54. An electroluminescent body wherein at least one of a lower electrode pattern and an upper electrode is transparent and there are, on a substrate, both a region where the lower electrode pattern and a patterning layer are formed in order from below and a region where the lower electrode pattern, a light emitting layer, and the upper electrode are formed in order from below.

55. An electroluminescent body according to claim 54, characterized in that said patterning layer is a water-repellent/oil-repellent layer.

56. An electroluminescent body according to claim 54, characterized by having a structure in which
a pattern is formed in both or one of at least the lower electrode and the upper electrode, and
the light emitting layer is formed in a region covering said electrode pattern.

57. An electroluminescent body according to claim 54, characterized by having a structure in which
a pattern is formed in both or one of at least the lower electrode and the upper electrode,
a region including a portion, corresponding to said electrode pattern, of the substrate is formed concave, and
the light emitting layer is formed in said concave region.

58. An electroluminescent body according to claim 54, characterized by having a structure in which
a pattern is formed in both or one of at least the lower electrode and the upper electrode,
an outer edge portion of a region, corresponding to said electrode pattern, of the substrate is formed convex, and
the light emitting layer is formed inside the convex region.

59. An electroluminescent body according to claim 54, characterized in that one or both of the lower electrode forming the pattern and the upper electrode contain at least one kind of titanium oxide, indium oxide, tin oxide, and indium-tin composite oxide (ITO).

60. An electroluminescent display device characterized by comprising the electroluminescent body according to claim 54.
